(19) United States
(12) Patent Application Publication
(10) Pub. No.: US 2018/0138903 A1
(43) Pub. Date: May 17, 2018

(54) LOW POWER CMOS BUFFER CIRCUIT

(71) Applicant: NXP USA, INC., Austin, TX (US)

(72) Inventor: Zhihong Cheng, Suzhou (CN)

(21) Appl. No.: 15/678,119

(22) Filed: Aug. 16, 2017

(30) Foreign Application Priority Data
Nov. 11, 2016 (CN) 201611047893.0

(51) Int. Cl. H03K 17/16

(52) U.S. Cl. CPC H03K 17/162; H03K 2217/0036

(57) ABSTRACT

A CMOS buffer circuit includes a first branch circuit having first and second transistors connected in parallel between a voltage source and ground, and a second branch having third and fourth transistors connected in parallel between the voltage source and ground. The gates of the first and second transistors receive an input signal. The gates of the third and fourth transistors are connected to a first node between the drains of the first and second transistors. An output signal is provided at a second node between the drains of the third and fourth transistors. The first and fourth transistors have conductive channels of a first type, and the second and third transistors have conductive channels of a second type that is different from the first type. In one embodiment, the first and fourth transistors are high threshold voltage transistors and the second and third transistors are low threshold voltage transistors.

### BACKGROUND

The present invention generally relates to a CMOS buffer circuit, and more particularly to a low power CMOS buffer circuit for high fan-out buffer trees.

A typical CMOS buffer includes at least one CMOS inverter. With very deep sub-micron technology, static power (leakage) becomes a significant issue for CMOS devices, such as Systems on a Chip (SOC). Using cells that have high-threshold voltages (high V_{T}) can effectively reduce leakage and thus, high V_{T} cells are widely used. However, drawbacks associated with high V_{T} cells include larger cell size, higher dynamic power, longer cell delay, etc. High fan-out buffer trees, like clock trees, set/reset trees, and scan related trees, consume a large portion of total silicon area as well as total power.

Accordingly, it would be advantageous to have a low leakage buffer cell that does not consume too much area, or power.

### SUMMARY

This summary is provided to introduce a selection of concepts in a simplified form that are further described below in the Detailed Description. This summary is not intended to identify key or essential features of the claimed subject matter, nor is it intended to be used to limit the scope of the claimed subject matter.

In one embodiment, the present invention provides a CMOS buffer circuit that includes a first branch circuit. The first branch circuit includes a first transistor with a conductive channel of a first type, and a second transistor with a conductive channel of a second type that is different from the first type. The gate terminals of the first and second transistors are coupled to receive an input signal, and the first transistor has a lower threshold voltage than the second transistor.

Embodiments hereof have the advantage of high V_{T} cells (low leakage), while having lower cell delay, smaller size, and lower dynamic power consumption than low V_{T} cells, which is especially useful in high fan-out buffer trees.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments. The drawings are for facilitating an understanding of the invention and thus are not necessarily drawn to scale. Advantages of the subject matter claimed will become apparent to those skilled in the art upon reading this description in conjunction with the accompanying drawings, in which like reference numerals have been used to designate like elements, and in which:

FIG. 1 is a schematic block diagram of an exemplary system including a CMOS buffer circuit of the present invention;

FIG. 2 is a schematic circuit diagram of a CMOS buffer circuit in accordance with a first embodiment, in which a first transistor has a higher V_{T} than a second transistor;

FIG. 3 is a schematic circuit diagram of a CMOS buffer circuit in accordance with a second embodiment, in which a fourth transistor has a higher V_{T} than a third transistor;

FIG. 4 is a schematic circuit diagram of a CMOS buffer circuit in accordance with a third embodiment of the present invention; and

FIG. 5 is a schematic diagram of a CMOS buffer circuit in accordance with a fourth embodiment of the present invention.

### DETAILED DESCRIPTION

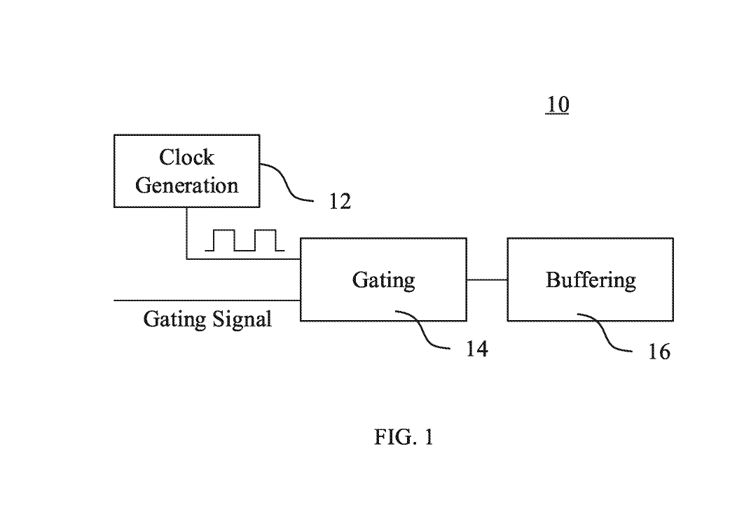

Referring now to FIG. 1, a system 10 that includes low power CMOS buffer circuits in accordance with an exemplary embodiment of the present invention is shown. The system 10 includes a clock generation circuit 12, a gating circuit 14, and a buffering or fan-out circuit 16. The clock generation circuit 12 generate a clock signal that is provided to the gating circuit 14. The gating circuit 14 further receives a gating signal and generates a gate signal. Optionally, the gating circuit 14 can include gate circuits like “AND” and “OR” gates that execute an AND or OR operations on the input clock signal and gating signal. For example, if the gating circuit 14 is implemented as an “AND” gate and the gating signal is logic low, the output gate signal will be logic low, regardless of the clock signal. If the gating circuit 14 is implemented as an “OR” gate and the input gating signal is logic high, the output gate signal will be logic high, regardless of the clock signal. The gate signal provided by the gating circuit 14 is provided to the fan-out circuit 16. The fan-out circuit 16 can include multiple CMOS buffer circuits in order to provide the gate signal to multiple destinations, e.g., registers, latches, SRAM, etc. of the system 10. As is known by those of skill in the art, CMOS buffer circuits can be used in various applications, such as fan-out buffer trees for buffering clock signals.

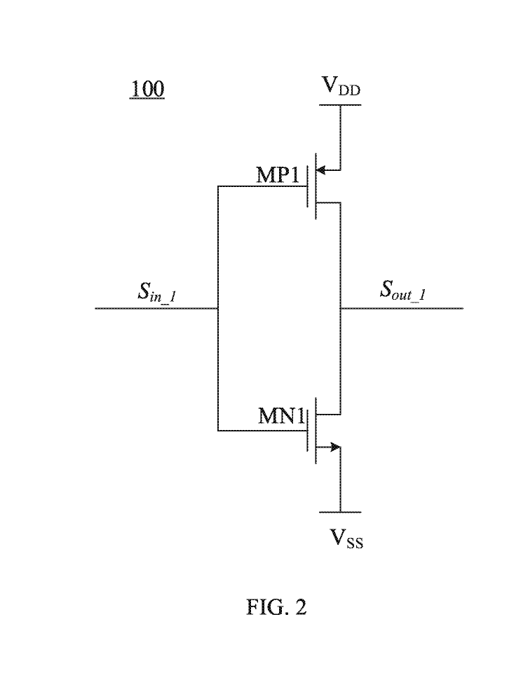

Referring to FIG. 2, a CMOS buffer circuit 100 according to a first embodiment of the present invention is illustrated. The CMOS buffer circuit 100 includes a first transistor MP1 and a second transistor MP2. Preferably, the first transistor MP1 is transistor with P-type channel, and the second transistor MN1 is a transistor with N-type channel. The gate terminals of the first and second transistors MP1 and MN1 are coupled together to receive an input signal Sᵢₙ_{_}₁. A source terminal of the first transistor MP1 is coupled to a supply voltage V_{DD}, and a drain terminal of the first transistor MP1 is coupled to a drain terminal of the second transistor MN1. A source terminal of the second transistor MN1 is coupled to a ground voltage V_{SS}. An output signal Sₒᵤₜ_{_}₁ of the CMOS buffer circuit 100 is provided at a node between the drains of the first and second transistors MP1 and MN1.

In a presently preferred embodiment, the first transistor MP1 has a higher threshold voltage V_{T} than the second transistor MN1. The threshold voltage VT of a transistor is a minimum voltage applied between its gate and source terminals for a channel to be created therein. When the input signal Sᵢₙ_{_}₁ is high (i.e., logic high level), then the first transistor MP1 is cut-off and the second transistor MN1 is conductive, and thus the output signal Sₒᵤₜ_{_}₁ is low. The CMOS buffer circuit 100 functions like an inverter. In use as a fan-out buffer for gated clock signals, if the gated clock signal is high in idle, then the CMOS buffer circuit 100 has a low leakage level because the first transistor MP1 is a high V_{T} transistor, while on the other hand, the second transistor MN1 has a lower cell delay, smaller size, and lower dynamic power.

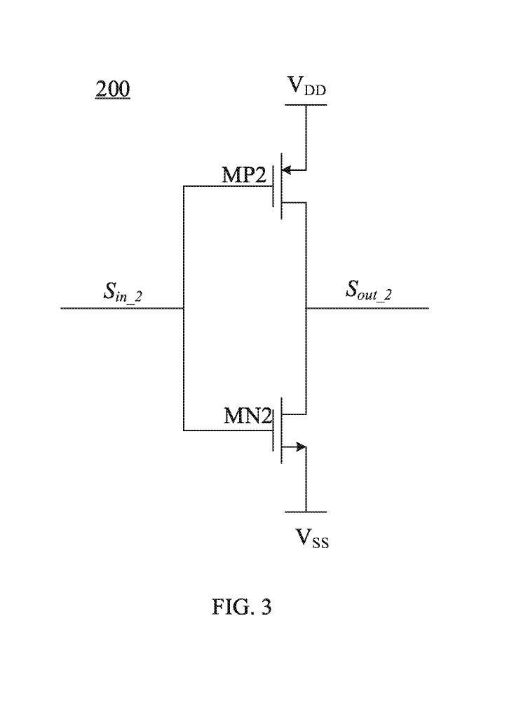

FIG. 3 illustrates another CMOS buffer circuit 200 according to a second embodiment of the present invention. The buffer circuit 200 has third and fourth transistors MP2 and MN2 connected in series between the supply voltage V_{DD} and ground V_{SS}. Further, the gates are connected together, as are the drains. A node between the gates receives an input signal Sᵢₙ_{_}₂ and an output signal Sₒᵤₜ_{_}₂ is provided at a node between the drains. Thus, general structure of the CMOS buffer circuit 200 is similar to that of the CMOS buffer circuit 100. However, the fourth transistor MN2 has a higher threshold voltage V_{T} than the third transistor MP2.

When the input signal Sᵢₙ_{_}₂ is low, as an example, the third transistor MP2 is conductive, and the fourth transistor MN2 is cut-off, so the output signal Sₒᵤₜ_{_}₂ is high. The CMOS buffer circuit 200 thus functions as an inverter. In use as a fan-out buffer for gated clock signals, if the gated clock signal is low in idle, the CMOS buffer circuit 200 will have a low level of leakage because the fourth transistor MN2 is a high V_{T} transistor, while on the other hand, the third transistor MP2 has less cell delay, smaller size, and lower dynamic power.

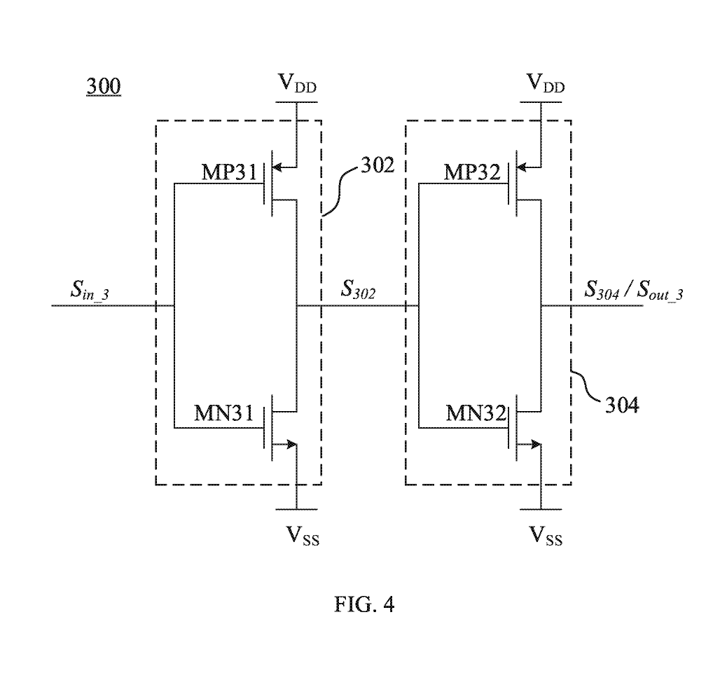

Referring to FIG. 4, a CMOS buffer circuit 300 in accordance with a third exemplary embodiment of the invention is illustrated. The CMOS buffer circuit 300 includes a first branch circuit 302 and a second branch circuit 304. The first branch circuit 302 receives an input signal Sᵢₙ_{_}₃ and provides a first buffered signal S₃₀₂. The second branch circuit 304 is coupled to the first branch circuit 302 to receive the first buffered signal S₃₀₂ and provide a second buffered signal S₃₀₄ as an output signal Sₒᵤₜ_{_}₃ of the CMOS buffer circuit 300.

The first branch circuit 302 is an inverter circuit, so the first buffered signal S₃₀₂ is an inverted version of the input signal Sᵢₙ_{_}₃. The second branch circuit 304 also is an inverter circuit, so the second buffered signal S₃₀₄ is an inverted version of the first buffered signal S₃₀₂.

The first branch circuit 302 includes a first transistor MP31 and a second transistor MN31, and the second branch circuit 304 includes a third transistor MP32 and a fourth transistor MN32. The first and second branch circuits 302 and 304 have similar structures and connections as the CMOS buffer circuits 100 and 200, respectively. In the first branch circuit 302, the first transistor MP31 has a higher threshold voltage V_{T} than the second transistor MN31; while in the second branch circuit 304, the fourth transistor MN32 has a higher threshold voltage V_{T} than the third transistor MP32.

When the input signal Sᵢₙ_{_}₃ is high, for example, then the first transistor MP31 is cut-off and the second transistor MN31 is conductive, so the first buffered signal S₃₀₂ is low. Then, in the second branch circuit 304, the third transistor MP32 is conductive while the fourth transistor MN32 is cut-off, so the second buffered signal S₃₀₄ is high. In application as a fan-out buffer for gated clock signals, if the gated clock signal is logic high in idle, then the first and second branch circuits 302 and 304 have a low level of leakage because the first and fourth transistors MP31, MN32 are high V_{T} transistors that have low leakages during cut-off, while on the other hand, the second and third transistors MN31 and MP32, which are low or lower V_{T} transistors, they have lower cell delay, smaller size, and lower dynamic power.

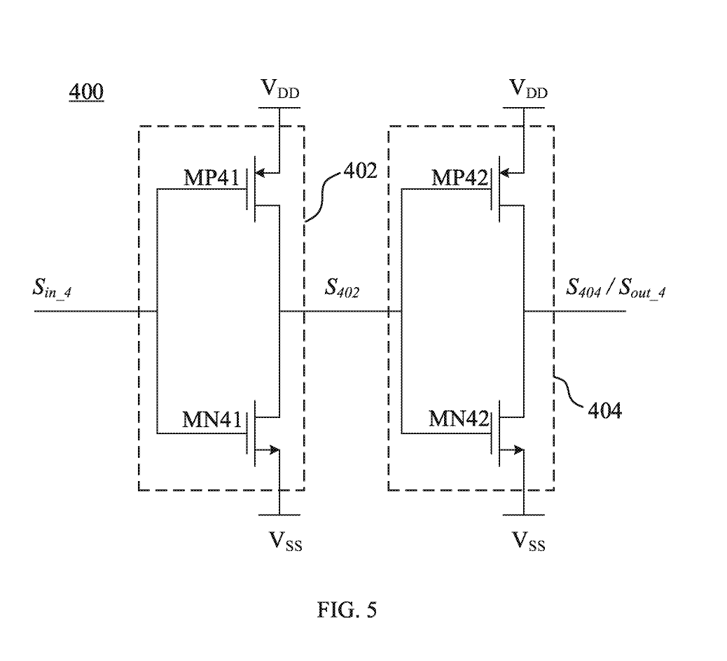

Referring to FIG. 5, a CMOS buffer circuit 500 in accordance with a fourth exemplary embodiment of the invention is illustrated. The CMOS buffer circuit 400 includes a first branch circuit 402 and a second branch circuit 404. The first branch circuit 402 is coupled to receive an input signal Sᵢₙ_{_}₄ and provide a first buffered signal S₄₀₂. The second branch circuit 404 is coupled to the first branch circuit 402 to receive the first buffered signal S₄₀₂ and provides a second buffered signal S₄₀₄ as an output signal Sₒᵤₜ_{_}₄ of the CMOS buffer circuit 400. The CMOS buffer circuit 400 has a similar structure and connection configuration as the CMOS buffer circuit 300 except that in the first branch circuit 402, the second transistor MN41 has a higher threshold voltage V_{T} than the first transistor MP41; while in the second branch circuit 404, the third transistor MP42 has a higher threshold voltage V_{T} than the fourth transistor MN42.

When the input signal Sᵢₙ_{_}₄ is low, in the first branch circuit 402, the first transistor MP41 is conductive and the second transistor MN41 is cut-off, so the first buffered signal S₄₀₂ is high. In the second branch circuit 404, the third transistor MP42 is cut-off and the fourth transistor MN42 is conductive, so the second buffered signal S₄₀₄ is logic low. In use as a fan-out buffer for gated clock signals, if the gated clock signal is logic low in idle, then the first and second branch circuits 402 and 404 have a low level of leakage because the second and third transistors MN41, MP42 are high V_{T} transistors that have low leakages during cut-off, while on the other hand, the first and fourth transistors MP41 and MN42 have lower cell delay, smaller size, and lower dynamic power.

Through the use of a mixed connection of a high V_{T} transistor and a low V_{T} transistor in a CMOS inverter, the CMOS buffer circuit has a controlled leakage while avoids excessive power consumption during cut-off of the high V_{T} transistor, while the low V_{T} transistor being conductive enables the CMOS buffer circuit to take the advantage of its limited device size, thereby allowing the size of the circuit to be at an acceptable scale, which can be especially helpful in high fan-out trees.

Turning back to FIG. 1, the fan-out circuit 16 can include multiple kinds of CMOS buffer circuits according to the embodiments described above with reference to FIGS. 2-5. In order to provide the advantages of both high V_{T} transistors and low V_{T} transistors in the CMOS buffer circuits, the fan-out circuit 16 has either the above-mentioned first embodiment or second embodiment (or alternatively between the third embodiment and the fourth embodiment, according to the practical requirement of whether an inverter is needed) in correspondence with a major status of the gated signal. The CMOS buffer circuits are selected per the major status of the input signal, such that the transistor with the high V_{T} will be cut-off and the low V_{T} transistors are conductive. Accordingly, the fan-out circuit will have a lower leakage during most of its operations, and thus lower overall power consumption.

By now it should be appreciated that there has been provided in some embodiments a CMOS buffer circuit which includes a first branch circuit, and the first branch circuit includes a first transistor with a conductive channel of a first type; and a second transistor with a conductive channel of a second type which is different from the first type; wherein gate terminals of the first transistor and the second transistor are coupled to receive an input signal; and the first transistor has a lower threshold voltage than the second transistor.

Preferably, the first transistor is a PMOS transistor, and the second transistor is an NMOS transistor, and preferably, the gate terminals of the first and second transistors are coupled together to receive an input signal with a logic low level.

It will be understood that the described “lower” or “higher” threshold voltage is expressed in order to show the relative relationship between the threshold voltages. In optional embodiments, an inverter circuit can be configured where one of the transistors has a high threshold voltage while another one of the transistors has a normal or only relatively lower threshold voltage in order to show a lowered threshold voltage. In other optional embodiments, one of the transistors can be configured to be normal while the other one thereof has a lowered threshold voltage. A transistor with a lowered V_{T} enables smaller size and in turn reduces the overall circuit size, as well as quicker response and lower dynamic power consumption.

The use of the terms “a” and “an” and “the” and similar referents in the context of describing the subject matter (particularly in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. Furthermore, the foregoing description is for the purpose of illustration only, and not for the purpose of limitation, as the scope of protection sought is defined by the claims as set forth hereinafter together with any equivalents thereof entitled to. The use of any and all examples, or exemplary language (e.g., “such as”) provided herein, is intended merely to better illustrate the subject matter and does not pose a limitation on the scope of the subject matter unless otherwise claimed. The use of the term “based on” and other like phrases indicating a condition for bringing about a result, both in the claims and in the written description, is not intended to foreclose any other conditions that bring about that result. No language in the specification should be construed as indicating any non-claimed element as essential to the practice of the invention as claimed.

Preferred embodiments are described herein, including the best mode known to the inventor for carrying out the claimed subject matter. Of course, variations of those preferred embodiments will become apparent to those of ordinary skill in the art upon reading the foregoing description. The inventor expects skilled artisans to employ such variations as appropriate, and the inventor intends for the claimed subject matter to be practiced otherwise than as specifically described herein. Accordingly, this claimed subject matter includes all modifications and equivalents of the subject matter recited in the claims appended hereto as permitted by applicable law. Moreover, any combination of the above-described elements in all possible variations thereof is encompassed unless otherwise indicated herein or otherwise clearly contradicted by context.

1. A CMOS buffer circuit comprising a first branch circuit, wherein the first branch circuit comprises:
a first transistor with a conductive channel of a first type; and
a second transistor connected in series with the first transistor, wherein the second transistor has a conductive channel of a second type that is different from the first type,
wherein gate terminals of the first and second transistors are coupled to receive an input signal, and
the first transistor has a lower threshold voltage than the second transistor.

2. The CMOS buffer circuit of claim 1, wherein the first transistor is a PMOS transistor, and the second transistor is a NMOS transistor.

3. The CMOS buffer circuit of claim 2, wherein a source terminal of the first transistor is coupled to a supply voltage, a drain terminal of the first transistor is coupled to a drain terminal of the second transistor, and a source terminal of the second transistor is coupled to a ground voltage.

4. The CMOS buffer circuit of claim 3, wherein a node between the drain terminals of the first and second transistors is configured to provide a buffered signal of the input signal.

5. The CMOS buffer circuit of claim 2, further comprising:
a second branch circuit including a third transistor with a conductive channel of the first type and a fourth transistor with a conductive channel of the second type,
wherein gate terminals of the third and fourth transistors are coupled to a node between the first transistor and the second transistor, and
wherein the third transistor has a higher threshold voltage than the fourth transistor.

6. The CMOS buffer circuit of claim 5, wherein the third transistor is a PMOS transistor, and the fourth transistor is a NMOS transistor.

7. The CMOS buffer circuit of claim 5, wherein a source terminal of the third transistor is coupled to the supply voltage, a drain terminal of the third transistor is coupled to a drain terminal of the fourth transistor, and a source terminal of the fourth transistor is coupled to the ground voltage.

8. The CMOS buffer circuit of claim 7, wherein a node between the drain terminals of the third and fourth transistors is configured to provide a buffered signal of the input signal.

9. The CMOS buffer circuit of claim 1, wherein the first transistor is a NMOS transistor, and the second transistor is a PMOS transistor.

10. The CMOS buffer circuit of claim 9, wherein a source terminal of the second transistor is coupled to a supply voltage, a drain terminal of the second transistor is coupled to a drain terminal of the first transistor, and a source terminal of the first transistor is coupled to a ground voltage.

11. The CMOS buffer circuit of claim 10, wherein a node between the drain terminals of the first and second transistors is configured to provide a buffered signal of the input signal.

12. The CMOS buffer circuit of claim 10, further comprising:
a second branch circuit including a third transistor with a conductive channel of the first type and a fourth transistor with a conductive channel of the second type,
wherein gate terminals of the third and fourth transistors are coupled to a node between the first and second transistors, and
wherein the third transistor has a higher threshold voltage than the fourth transistor.

13. The CMOS buffer circuit of claim 12, wherein the third transistor is an NMOS transistor, and the fourth transistor is a PMOS transistor.

14. The CMOS buffer circuit of claim 12, wherein a source terminal of the fourth transistor is coupled to a supply voltage, a drain terminal of the fourth transistor is coupled to a drain terminal of the third transistor, and a source terminal of the third transistor is coupled to a ground voltage.

15. The CMOS buffer circuit of claim 14, wherein a node between the drain terminals of the third and fourth transistors is configured to provide a buffered signal of the input signal.

16. The CMOS buffer circuit of claim 12, wherein the first branch circuit is a first inverter circuit, and the second branch circuit is a second inverter circuit.

17. The CMOS buffer circuit of claim 1, wherein the first transistor has a normal or lowered threshold voltage, and the second transistor has an increased threshold voltage.

18. The CMOS buffer circuit of claim 1, wherein the second transistor has a normal threshold voltage and the first transistor has a lower threshold voltage than the second transistor.

19. A low power CMOS buffer circuit, comprising:
a first branch circuit including first and second transistors connected in series between a source voltage and a ground voltage; and
a second branch circuit including third and fourth transistors connected in series between the source voltage and the ground voltage, wherein the third transistor has a conductive channel of the second type and the fourth transistor has a conductive channel of a first type,
wherein gate terminals of the first and second transistors are coupled to receive an input signal, gate terminals of the third and fourth transistors are connected to a first node between the drain terminals of the first and second transistors, and an output signal is provided at a second node between the drain terminals of the third and fourth transistors, and
wherein the first and fourth transistors are low threshold voltage transistors and the second and third transistors are high threshold voltage transistors.

20. The low power CMOS buffer circuit of claim 19, wherein the first and third transistors have conductive channels of a first type and the second and fourth transistors have conductive channels of a second type that is different from the first type.
